(19) United States
(12) Patent Application Publication
(10) Pub. No.: US 2016/0300809 A1
(43) Pub. Date: Oct. 13, 2016

(54) Lead-Free Solder Alloy and Semiconductor Device

(71) Applicant: HITACHI, LTD., Chiyoda-ku, Tokyo (JP)

(72) Inventors: Takaaki MIYAZAKI, Tokyo (JP); Osamu IKEDA, Tokyo (JP)

(73) Assignee: HITACHI, LTD., Chiyoda-ku, Tokyo (JP)

(21) Appl. No.: 15/037,342

(22) PCT Filed: Nov. 20, 2013
(86) PCT No.: PCT/JP2013/081275

§ 371 Date: May 18, 2016

(51) Int. Cl. H01L 23/00; B23K 35/26; B23K 35/02; C22C 13/00

(52) U.S. Cl. CPC H01L 24/29; C22C 13/00; B23K 35/262; B23K 35/0233; H01L 2924/01029; H01L 2924/01083; H01L 2924/01051; H01L 2924/01049; H01L 2924/0105; H01L 2924/014; H01L 2924/15787; H01L 2924/1203; H01L 2924/3512; H01L 2224/29655; H01L 2224/29564

(57) ABSTRACT

A semiconductor device 20 has: a semiconductor chip 1; a connected member 5 connected to the semiconductor chip 1 via a solder alloy (lead-free solder alloy) 2; and an external terminal electrically connected to the semiconductor chip 1. The above-described solder alloy 2 of the semiconductor device 20 is composed of: Cu of 5 to 10 weight %; any one, two, or more of Bi of 1 weight % or more and 4 weight % or less, Sb of 1 weight % or more and less than 10 weight %, and In of 1 weight % or more and 4 weight % or less; and Sn as a residual.

### TECHNICAL FIELD

The present invention relates to a lead-free solder alloy and a semiconductor device, and, more particularly, the present invention relates to a lead-free solder alloy that is used under a high-temperature environment and a semiconductor device using the same.

### BACKGROUND ART

Lead is generally contained in the solder serving as the connection member used in electric connection of the components of electric/electronic devices. However, in recent years, as environmental consciousness increases, regulations for the lead which is pointed out to be hazardous to human bodies have started.

In Europe, the ELV Directive (End-of Life Vehicles directive, directive about a discarded automobile) which limits usage of the lead in an automobile and the RoHS (Restriction of the use of certain Hazardous Substances in electrical and electronic equipment) directive which prohibits usage of the lead in electric/electronic devices have been enforced.

In the past, lead (Pb)-containing solder has been used as the connection member of the semiconductor device which is required to have high thermal resistance, more particularly, a semiconductor device used in the fields of automobiles, construction machines, railways, and information devices, etc. However, in order to reduce the environmental load, it is strongly required to use a lead-free connection member.

Moreover, in recent years, development of a wide-gap semiconductor such as SiC and GaN which can operate at a high temperature and which can downsize a device has been promoted. Note that, while the upper limit of the operation temperature of a Si (silicon) semiconductor element is 150 to 175° C., usage of a SiC semiconductor element is expected to be at 175° C. or higher.

When the usage environmental temperature is high, a reaction of a connection interface advances fast, and therefore, the stability of the interface is required. Moreover, conduction and shut-off of a current to the element is repeated, and therefore, thermal stress is repeatedly applied thereto. Therefore, resistance to current-conduction thermal fatigue, resistance to cracking caused by change in an environmental temperature, and compatibility to multi-stage solder connections are also required.

In order to support the above-described requirements, a lead-free highly-reliable connection technique having a high thermal resistance is required.

As such a high-temperature solder alloy, in a technique described in, for example, a Patent Document 1, any one, two, or more of elements Co, Fe, Mo, Cr, Ag, and Bi is added to a solder composition composed of Sb 10 to 40 mass %, Cu 0.5 to 10 mass %, and the residual Sn as a composition of a soldered part, and either one or more of Ge and Ga is added thereto as an antioxidant element in order to improve a mechanical strength.

Meanwhile, a technique described in a Patent Document 2 discloses a lead-free solder alloy which has a composition of Sb of 1 to 10 weight %, Cu of 1 to 4 weight %, Bi of 1 to 6 weight %, In of 1 to 5 weight %, and the residual Sn and whose solidus temperature is 200° C. or higher as a lead-free solder alloy used in a hybrid IC having an electronic component and a circuit conductor of calcined copper when the above-described electronic component and the above-described circuit conductor are soldered by reflow.

### RELATED ART DOCUMENTS

### Patent Documents

Patent Document 1: Japanese Patent Application Laid-Open Publication No. 2009-255176

Patent Document 2: Japanese Patent Application Laid-Open Publication No. H11-77368

### SUMMARY OF THE INVENTION

### Problems to be Solved by the Invention

The technique described in the above described Patent Document 1 has such a problem that an element is cracked when thermal stress is applied thereto since 10 to 40 mass % of Sb is contained therein to harden the solder alloy and such a problem that the progress of the cracking becomes fast to reduce reliability.

Meanwhile, in the technique described, in the above-described Patent Document 2, when Cu and the lead-free solder alloy are connected to each other while the alloy contains Cu of 1 to 4 weight %, interface stability cannot be maintained in an environment at 175° C. or higher since Cu and the Cu—Sn compound are brought into direct contact with each other.

Also, a case of connection to a member with Ni plating formed thereon has such a problem that interface stability cannot be maintained in an environment at 175° C. or higher to reduce reliability since many Cu—Sn—Ni compounds having a small effect of preventing interface diffusion are formed on a connecting interface.

An object of the present invention is to provide a technique that can improve the connecting reliability of solder connection between the lead-free solder alloy and the semiconductor device in a high-temperature environment.

The above and other object and novel characteristics of the present invention will be apparent from the description of the present specification and the accompanying drawings.

### Means for Solving the Problems

The typical summary of the inventions disclosed in the present application will be briefly described as follows.

A lead-free solder alloy of the present invention has a solder composition composed of: Cu of 5 to 10 weight %; any one, two, or more of Bi of 1 weight % or more and 4 weight % or less, Sb of 1 weight % or more and less than 10 weight %, and In of 1 weight % or more and 4 weight % or less; and Sn as a residual.

A semiconductor device of the present invention has: a semiconductor chip; a chip supporting member connected to the semiconductor chip via a lead-free solder alloy; and an external terminal electrically connected to the semiconductor chip. The above-described lead-free solder alloy is composed of Cu of 5 to 10 weight %; any one, two, or more of Bi of 1 weight % or more and 4 weight % or less, Sb of 1 weight % or more and less than 10 weight %, and In of 1 weight % or more and 4 weight % or less; and Sn as a residual.

### Effects of the Invention

The effects obtained by typical aspects of the present invention will be briefly described below.

The connection reliability of solder connection between the lead-free solder alloy and the semiconductor device in a high-temperature environment can be improved.

### BRIEF DESCRIPTIONS OF THE DRAWINGS

FIG. 1 is a partial cross-sectional view showing an example of a structure of a principal part of a semiconductor device of an embodiment of the present invention;

FIG. 2 is a partial cross-sectional view showing an example of structures obtained before and after connection of a solder connection part of the semiconductor device shown in FIG. 1;

FIG. 3 is an enlarged partial cross-sectional view showing a structure of a part “A” of the semiconductor device shown in FIG. 1;

FIG. 4 is a plan view showing an example of a horizontal-direction structure of a solder alloy layer shown in FIG. 1;

FIG. 5 is a plan view showing an example of a horizontal-direction structure of the solder alloy layer shown in FIG. 1 obtained after a temperature cycle test;

FIG. 6 is a data diagram showing a ratio of a Cu—Sn compound with respect to an additive amount of Cu in the lead-free solder alloy of the embodiment of the present invention and an example of a Ni-plating losing thickness;

FIG. 7 is a partial cross-sectional view showing a structure of a connection interface obtained in connection using a solder alloy of a comparative example;

FIG. 8 is a partial cross-sectional view showing a structure of a connection interface obtained in connection using the lead-free solder alloy of the embodiment of the present invention;

FIG. 9 is a cross-sectional view showing an example of a structure of a semiconductor device (semiconductor module) using the lead-free solder alloy of the embodiment of the present invention;

FIG. 10 is a cross-sectional view showing an example of a structure of a semiconductor device (alternating-current-generator semiconductor module) using the lead-free solder alloy of the embodiment of the present invention;

FIG. 11 is an evaluation result diagram showing results of evaluations of each example of the present invention and comparative example;

FIG. 12 is an evaluation result diagram showing results obtained when a current-conduction thermal fatigue test is performed to the solder alloys of some examples and comparative examples shown in FIG. 11;

FIG. 13 is a partial side view showing an example of a railway vehicle on which a semiconductor device using the lead-free solder alloy of the embodiment of the present embodiment is mounted; and

FIG. 14 is a plan view showing an example of an internal structure of an inverter set or a vehicle shown in FIG. 13.

### DESCRIPTIONS OF THE PREFERRED EMBODIMENTS

In the following embodiments, the description of the same or similar components are not repeated in principle unless otherwise required.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Also, when “formed of A”, “formed by A”, “having A”, or “including A” is described for components or the like in the following embodiments, it goes without saying that other components are not eliminated unless otherwise specified to be only the component. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference symbols throughout all the drawings for describing the embodiments, and the repetitive description thereof will be omitted. Also, hatching is used even in a plan view so as to make the drawings easy to see.

<Embodiment>

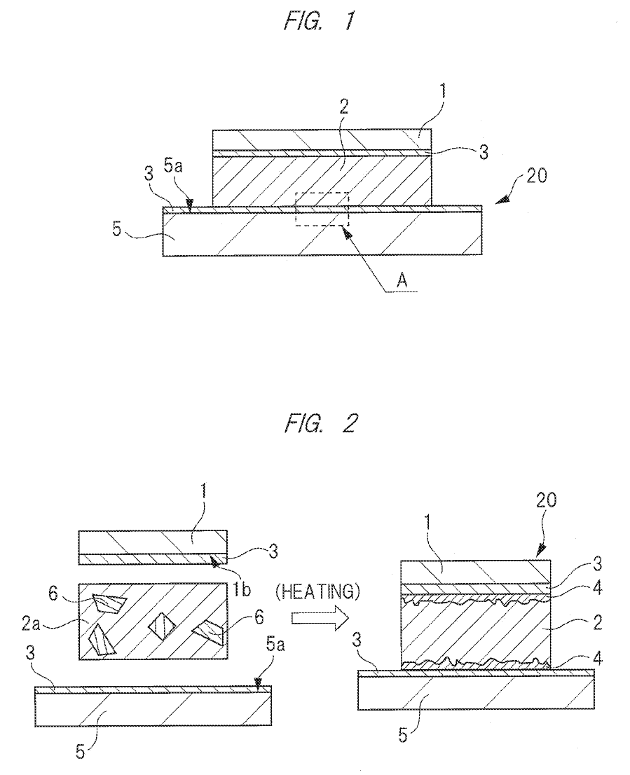

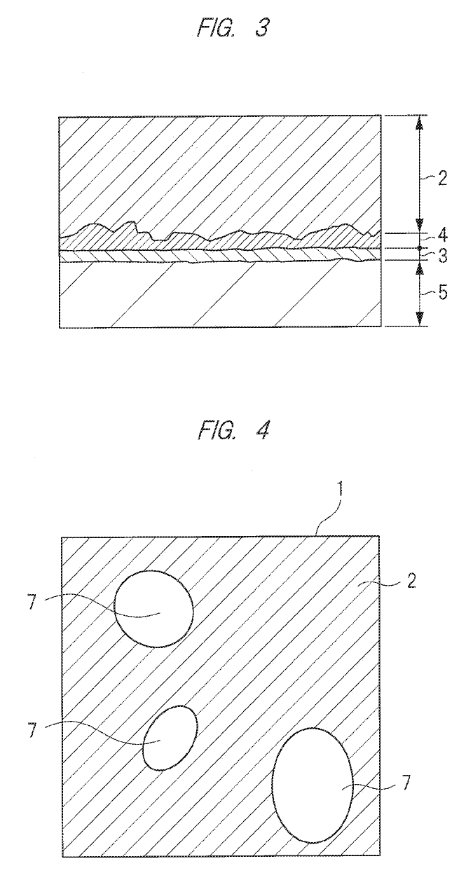

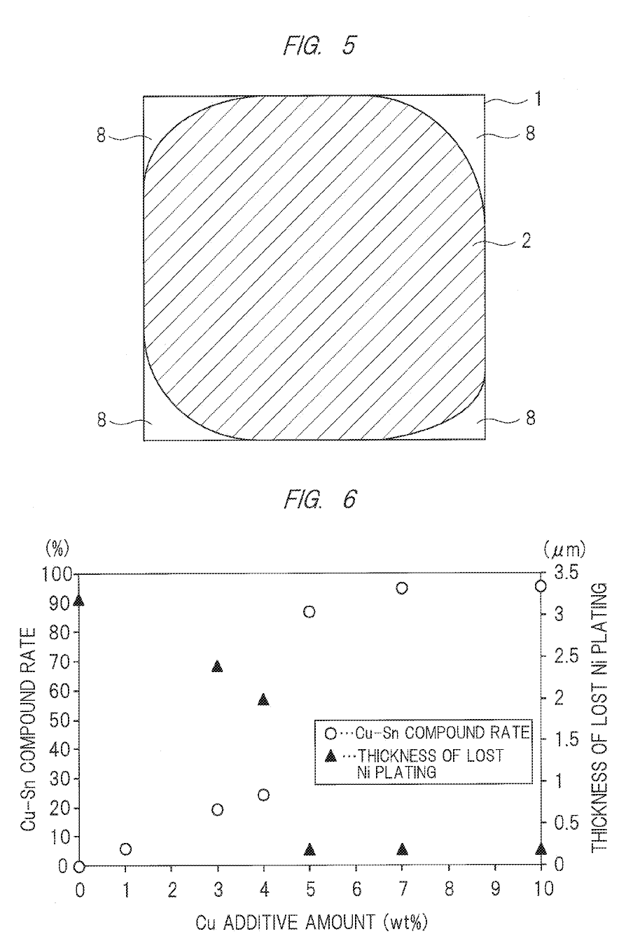

FIG. 1 is a partial cross-sectional view showing an example of a structure of a principal part of a semiconductor device of an embodiment of the present invention, FIG. 2 is a partial cross-sectional view showing an example of a structure obtained before and after connection of a solder connection part of the semiconductor device shown in FIG. 1, and FIG. 3 is an enlarged partial cross-sectional view showing a structure of a part “A” of the semiconductor device shown in FIG. 1. Furthermore, FIG. 4 is a plan view showing an example of a horizontal-direction structure of a solder alloy layer shown in FIG. 1, and FIG. 5 is a plan view showing an example of a horizontal-direction structure of a solder alloy layer shown in FIG. 1 obtained after a temperature cycle test.

First, the configuration of the principal part of the semiconductor device using the lead-free solder alloy of the present embodiment shown in FIG. 1 will be described.

In a semiconductor device 20 shown in FIG. 1, a semiconductor chip 1, which is a semiconductor element, is solder-connected onto a ceramic substrate (insulating substrate) 5, which is a chip supporting member, via a solder alloy (lead-free solder alloy) 2.

Note that the solder alloy 2 is the solder not containing lead (Pb).

Furthermore, a Ni plating layer 3 is formed on a front surface of an upper surface 5a of the ceramic substrate 5, and the solder alloy 2 is arranged on the Ni plating layer 3. Moreover, a Ni plating layer 3 is formed also on a connection part between the solder alloy 2 and the semiconductor chip 1.

Then, assembly of the principal part of the semiconductor device 20 will be described by using FIG. 2. First, solder foil 2a is sandwiched by the semiconductor chip 1 and the ceramic substrate 5 which is the chip supporting member with the Ni plating layer 3 formed thereon.

That is, the solder foil 2a is arranged on the Ni plating layer 3 of the ceramic substrate 5 having the surface of the upper surface 5a on which the Ni plating layer 3 is formed, and besides, the semiconductor chip 1 having a back surface 1b on which the Ni plating layer 3 is formed is arranged on the solder foil 2a so that the solder foil 2a is sandwiched by the ceramic substrate 5 and the semiconductor chip 1.

Note that a Cu—Sn compound 6 is contained in the solder foil 2a. Then, the structure in which the solder foil 2a is sandwiched by the semiconductor chip 1 and the ceramic substrate 5 is heated to 280° C. or higher. By the above-described heating, the Cu—Sn compound (for example, Cu₆Sn₅) 6 is precipitated or moved onto the connection interface, and a Cu—Sn-based compound layer 4 is formed on the Ni plating layers 3 (on the solder alloy 2 side).

Meanwhile, Bi, In, and Sb contained in the solder are caused to be in a state of solid solution in a Sn phase. As the structure obtained after the connection as shown after the heating in FIG. 2, the Cu—Sn-based compound layer 4 is formed on the Ni plating layer 3 generated on the ceramic substrate 5, and the solder alloy 2 mainly composed of Sn in which the sold solution of Bi, In, and Sb contained in the solder is caused is formed during the formation.

FIG. 3 shows a detailed structure of the part “A” of the solder connection part shown in FIG. 1, in which even in exposure to a high-temperature environment of 175° C. or higher for a long period of time, a compound layer mainly composed of the Cu—Sn-based compound layer 4 serves as a barrier layer between the connection interface and the solder alloy 2. As a result, growth of the compound layer caused by reactions at the connection interface and formation of voids along with the growth can be suppressed. Moreover, by the solid solution of Bi, In, and Sb in the Sn phase, mechanical characteristics can be improved, and reliability such as resistance to crack progress at high temperature can be improved.

In the connection part of the solder alloy 2 of the semiconductor device 20 including the semiconductor chip 1 and the ceramic substrate 5 connected as described above, FIG. 4 shows a result of measuring a void area rate by ultrasonic flaw detection. The void rate is calculated by dividing the total area of voids 7 by a planar-direction area of a connection layer in a planar direction of the solder alloy 2 (hatched part of FIG. 4) which is the connection part.

Herein, the cracks generated in a solder layer in a temperature cycle test will be described. FIG. 5 shows cracks generated in the solder connection part due to thermal stress after the temperature cycle rest of about 500 cycles is performed in such setting that 15 minutes at −55° C. and 15 minutes at 200° C. are performed as 1 cycle.

A crack progress rate of the solder connection part of the semiconductor device 20 tested as described above and shown in FIG. 2 is measured by ultrasonic flaw detection. The crack progress rate is calculated by dividing a total area of a crack progressed part 8 by the planar-direction area of the connection layer in the planar direction of the solder alloy 2 (hatched part of FIG. 5) which is the connection part.

Note that the void rate in excess of 10% causes such a problem that the cracks preferentially progress from peripheries of the voids, which results in reduction in reliability at an early stage and others. Therefore, by reducing the void rate, the reliability can be ensured for a long period of time.

Meanwhile, heat is generated by the current conduction of the semiconductor chip 1, and the crack progress rate in excess of 20% deteriorates the release of the heat generated in the semiconductor chip 1, and therefore, the temperature in the vicinity of the semiconductor chip is increased, and the reliability is rapidly reduced.

Herein, as the materials of the connected members such as the semiconductor chip 1 and the substrate, various metals and alloys such as Cu, Ni, Au, Ag, Pt, Pd, Ti, TiN and Fe-based alloys such as Fe—Ni and Fe—Co can be applied. However, the connected members are preferably subjected to Ni metalization.

This is because, as shown in FIG. 2, the connection interface can be stably maintained by the formation of the barrier layer of the Cu—Sn-based compound layer 4 on the Ni plating layer 3, so that better reliability can be maintained in a high-temperature environment.

Note that, if the metalization on the surface of the connected member is performed with Ni, oxidation of Ni itself becomes a problem, and wettability may be inhibited. Therefore, Au, Ag, Pt, and Pd which are difficult to be oxidized may be stacked on Ni. In other words, the surface of the connected member is preferably subjected to metalization of Ni, Ni/Au, Ni/Ag, etc.

Because of such metalization, as the semiconductor chip 1, even the semiconductor chip 1 of any of Si, SiC, GaAs, CdTe, GaN, etc., can be connected. By a state that the substrate is also subjected to the above-described metalization, highly reliable connection can be achieved to any member such as Cu, Al, 42 alloy, a ceramic substrate (insulating substrate) pasted with metal such as CIC (Copper Invar Copper), DBC (Direct Bond Copper), or DBA (Direct Bond Aluminum) or others.

Note that, when the structure obtained after the connection in the case of the connection by the solder alloy 2 of the present embodiment is described in detail, the Ni-metalized connected member is as “the connected member”/Ni/“Cu—Sn-based compound”/“solder alloy”/“Cu—Sn-based compound”/Ni/“the connected member”.

In the above-described example, the connection between the semiconductor chip 1 and the substrate has been described. However, such a configuration can be applied also to the connection between the semiconductor chip 1 and a lead, between the semiconductor chip 1 and a heat-releasing substrate (member), between the semiconductor chip 1 and a frame, between the semiconductor chip 1 and an insulating substrate, or between the semiconductor chip 1 and a general electrode.

Moreover, the configuration described above is not limited to the connection between the semiconductor chip 1 and the substrate, but can be also generally applied to a case of connection between a first connected member and a second connected member by the connected member of the present embodiment. For example, this can be also applied to the connections between a metal plate and a metal plate, between a metal plate and a ceramic substrate, etc.

Next, specifically-evaluated example and comparative example will be described.

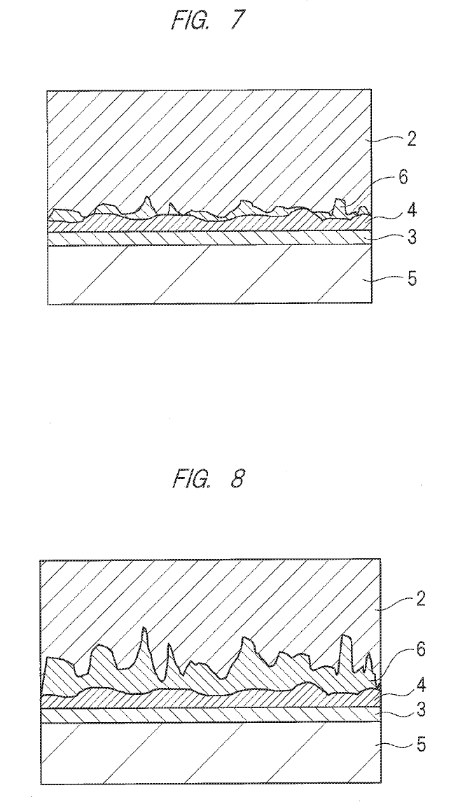

FIG. 6 is a data diagram showing an example of a ratio of the Cu—Sn compound with respect to the additive amount of Cu in the lead-free solder alloy of the embodiment of the present invention and an example of a Ni-plating losing thickness, FIG. 7 is a partial cross-sectional view showing a structure of a connection interface obtained in a case of connection using a solder alloy of the comparative example, and FIG. 8 is a partial cross-sectional view showing a structure of a connection interface in a case of connection using the lead-free solder alloy of the embodiment of the present invention.

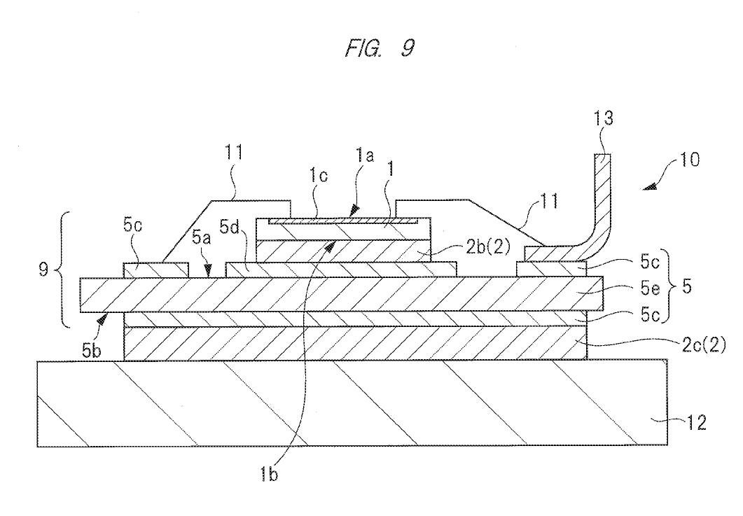

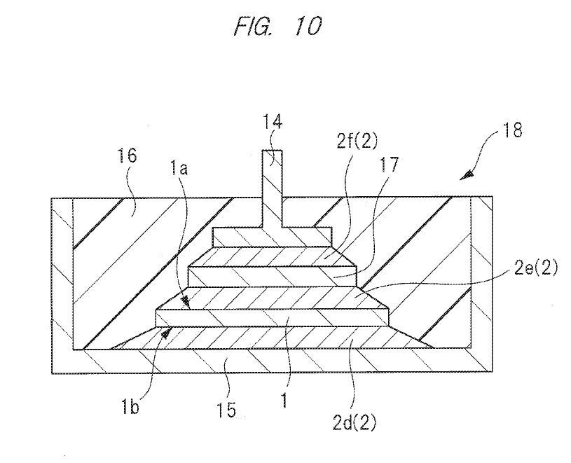

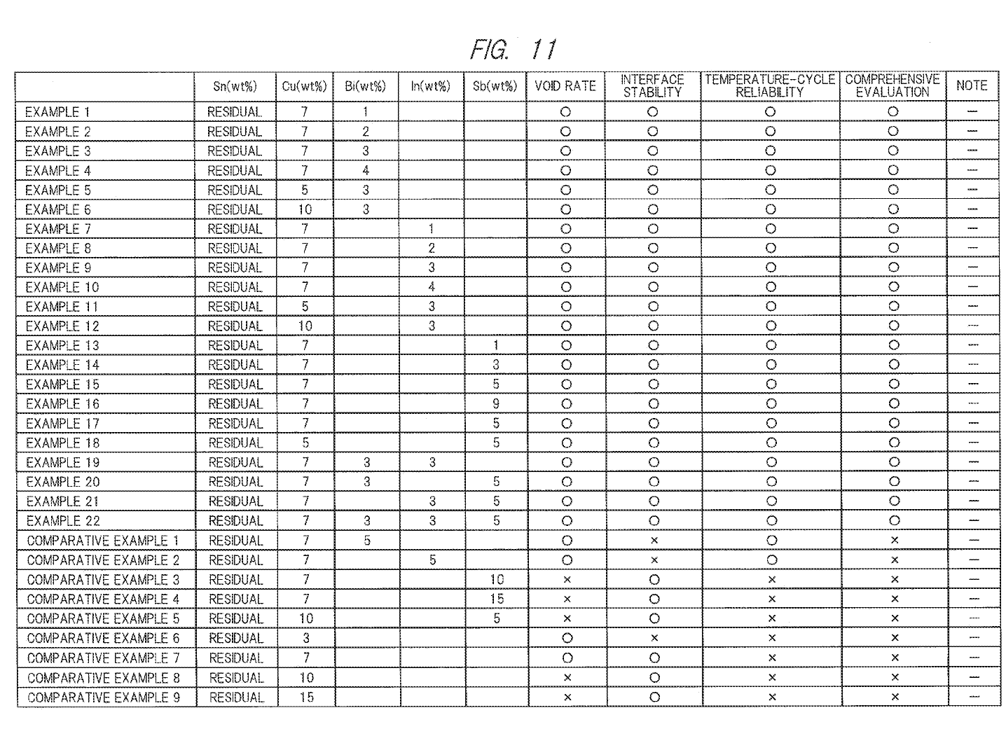

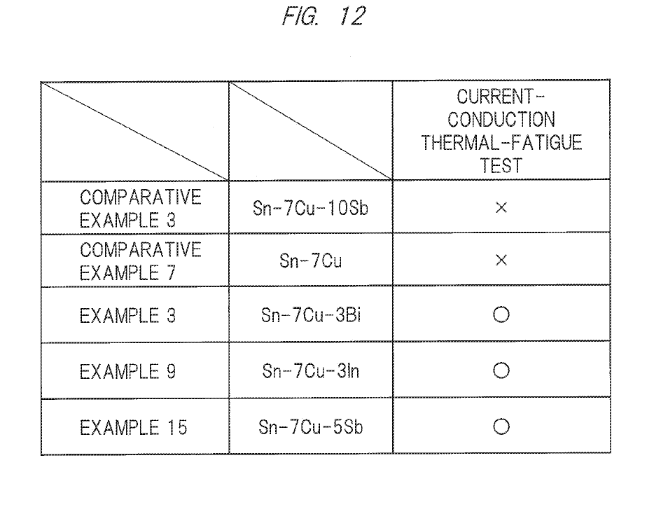

Meanwhile, FIG. 9 is a cross-sectional view showing an example of a structure of a semiconductor module using the lead-free solder alloy of the embodiment of the present invention, and FIG. 10 is a cross-sectional view showing an example of a structure of an alternating-current-generator semiconductor module using the lead-free solder alloy of the embodiment of the present invention. Furthermore, FIG. 11 is an evaluation result diagram showing the results of evaluations of each example of the present invention and comparative example, and FIG. 12 is an evaluation result diagram showing the results of a current-conduction thermal fatigue test performed to the solder alloys of some of examples and comparative examples shown in FIG. 11.

Hereinafter, evaluation results of examples 1 to 22 and comparative examples 1 to 9 shown in FIG. 11 will be described. First, FIG. 11 shows the results of evaluations of the void rate, interface stability, and temperature cycle reliability, and besides, comprehensive evaluations performed after manufacturing each of semiconductor devices 20 under the conditions shown in the examples 1 to 22 and the comparative examples 1 to 9.

In the semiconductor devices 20, first, note that a chip structure is formed by stacking a connected member 5 which is a Ni-plated Cu plate of 15-mm square, a connecting member which is a solder foil 2a under the conditions of the examples 1 to 22, and a semiconductor chip 1 of 10-mm square plated with Ni having a thickness of 0.3 mm. Then, the semiconductor device 20 is manufactured by connecting the chip structure in a N₂+4% H₂ atmosphere under a temperature condition at 320° C. for 5 minutes using a thermal treatment furnace.

In the evaluations, note that a symbol “O” represents the cases that the void rate of the connection layer which is a general criterion in which certain reliability can be obtained in the semiconductor device 20 is 10% or less so that the semiconductor chip us normally operated, and a symbol “X” represents the other cases.

Also, a symbol “O” represents the cases that the crack progress rate which is a general reliability criterion is measured and is 20% or less after a temperature cycle test of about 500 cycles in a case of a condition of 15 minutes at −55° C. and 15 minutes at 200° C. set as 1 cycle so that the semiconductor chip 1 is normally operated, and a symbol “X” represents the other cases.

Regarding the interface stability, a symbol “O” represents the cases that Ni plating remains after retention at 200° C. for 1000 hours, and a symbol “X” represents the cases that loss of the Ni plating is even partially confirmed. This is because the loss of the Ni plating advances the diffusion between the connected member and the solder alloy, an intermetallic compound is formed, and voids are generated due to volume differences, and therefore, the long-term reliability cannot be maintained.

In the comprehensive evaluation, a symbol “O” represents the cases in which the evaluations in all the conditions are “O”, and a symbol “X” represents the other cases.

Next, the additive amount of Cu (Cu: 5 weight (wt) % or more and 10 weight (wt) % or less) will be described.

FIG. 6 shows the relation among the additive amount of Cu, the rate of the Cu—Sn compound, and the Ni-plating losing thickness. As seen from FIG. 6, if the additive amount of Cu is increased, the decrease amount of the Ni plating is reduced (the remaining amount of the Ni plating is increased). The loss of the Ni plating progresses the reaction between the connected member and the solder alloy, and forms the voids, and therefore, reduces the reliability.

Therefore, the smaller the Ni-plating losing amount is, the higher the interface stability is, and therefore, the Ni-plating losing amount becomes an indicator of reliability improvement. Meanwhile, increase in the additive amount of Cu increases the rate of the compounds in the solder alloy, increases a viscosity in the solder melting, and increases the void rate.

Note that the remaining amount of the Ni plating is rapidly increased if the additive amount of Cu is 5 wt % or more. Regarding this, the Cu—Ni—Sn compound (Cu—Sn-based compound layer 4) and the Cu—Sn compound 6 are formed in this order on the Ni-plating layer 3 of the connection part interface as shown in the comparative example of FIG. 7. However, as shown in FIG. 8, if the additive amount of Cu becomes 5 wt % or more, the rate of the Cu—Sn compound 6 formed on the connection interface is rapidly increased. In the Cu—Sn compound 6, diffusion of the Ni plating in a high-temperature environment is strongly suppressed more than the Cu—Ni—Sn compound (Cu—Sn-based compound layer 4), and therefore, high reliability can be obtained.

On the other hand, as shown in the comparative examples 5, 8, and 9, if the additive amount of Cu is larger than 10 wt %, the void rate exceeds 10%, and a result of the evaluation becomes “X”.

As described above, when Cu is added by 5 weight (wt) % or more and 10 weight (wt) % or less, good connection reliability can be obtained.

Next, the additive amount of Bi (bismuth) (Bi: 1 weight % or more and 4 weight % or less) will be described.

By adding Bi by 1 wt % or more in the examples 1 to 6 shown in FIG. 11, a result of the temperature-cycle reliability becomes “O”. On the other hand, when Bi is added by more than 5 wt % as shown in the comparative example 1, the stability of the connection interface is deteriorated, and the reliability cannot be maintained (a result of the interface stability becomes “X”). This is because the increase in the additive amount of Bi precipitates the Bi phase, furthermore, Bi has high reactivity with Ni, and therefore, the stability of the interface is deteriorated.

Next, the additive amount of In (indium) (In: 1 weight % or more and 4 weight % or less) will be described.

By adding In by 1 wt % or more in the examples 7 to 12 shown in FIG. 11, a result of the temperature-cycle reliability becomes “O”. On the other hand, by adding In by more than 4 wt % as shown in the comparative example 2, the stability of the connection interface is deteriorated, and the reliability cannot be maintained (a result of the interface stability becomes “X”). The increase in the additive amount of In decreases the solidus temperature, and decreases the long-term reliability in combination with the decrease in barrier effects because the Cu—Sn—In compound is formed in the connection interface.

Next, the additive amount of Sb (antimony) (Sb: 1 weight % or more and 10 weight % or less) will be described.

By adding Sb by 1 wt % or more in the examples 13 to 18 shown in FIG. 11, a result of the temperature-cycle reliability becomes “O”. On the other hand, if Sb is added by 10% or more as shown in the comparative examples 3 and 4, the evaluation results of the void rate become “X”, and a result of the temperature-cycle reliability also becomes “X”. This is because the increase in the additive amount of Sb increases the precipitated amount of the Sn—Sb compound in the solder, and increases the viscosity of the solder, furthermore, increases the void rate, and hardens the solder, and therefore, decreases the temperature-cycle reliability.

As shown in the examples 19 to 22 of FIG. 11, note that good temperature-cycle reliability, void rate, and interface stability have been obtained also when two or more types of Bi, In, and Sb are added.

As described above, the lead-free solder alloy of the present embodiment has a solder composition composed of: Cu of 5 to 10 weight %; Sn as a residual; and any one, two, or more of Bi of 1 weight % or more and 4 weight % or less; Sb of 1 weight % or more and less than 10 weight %; and In of 1 weight % or more and 4 weight % or less.

Specifically, Bi among Bi, Sb, and In is added by 1 weight % or more and 4 weight % or less (examples 1 to 6) into the solder alloy composed of Cu of 5 to 10 weight % and the residual Sn, or In is added by 1 weight % or more and 4 weight % or less (examples 7 to 12) thereto, or Sb is added by 1 weight % or more and 10 weight % or less (examples 13 to 18) thereto.

Furthermore, into the solder alloy composed of Cu of 5 to 10 weight % and the residual Sn, Bi among Bi, Sb, and In is added by 1 weight % or more and 4 weight % or less, and In is added by 1 weight % or more and 4 weight % or less (example 19). Alternatively, into the solder alloy composed of Cu of 5 to 10 weight % and the residual Sn, Bi is added by 1 weight % or more and 4 weight % or less, and Sb is added by 1 weight % or more and less than 10 weight % (example 20). Alternatively, into the solder alloy composed of Cu of 5 to 10 weight % and the residual Sn, In is added by 1 weight % or more and 4 weight % or less, and Sb is added by 1 weight % or more and less than 10 weight % (example 21).

Furthermore, into the alloy composed of Cu of 5 to 10 weight % and the residual Sn, Bi is added by 1 weight % or more and 4 weight % or less, Sb is added by 1 weight % or more and less than 10 weight %, and In is added by 1 weight % or more and 4 weight % or less (Example 22).

As described above, in any of the combinations, as shown in the examples 1 to 22 of FIG. 11, “O” can be obtained (good results can be obtained) as the result of the void rate, the interface stability, the temperature-cycle reliability, and the comprehensive evaluation. That is, in the solder connections using the lead-free solder alloys shown in the examples 1 to 22, the connection reliability of the solder connection can be improved even in a high-temperature environment.

Moreover, by using the lead-free solder alloys of the examples 1 to 22 of FIG. 11, the cracking of the semiconductor chip 1 can be prevented even when the thermal stress is applied to the semiconductor device 20. Furthermore, the advance of the cracks to the semiconductor chip 1 can be slow to increase the reliability of the semiconductor chip 1.

Furthermore, by using the lead-free solder alloys of the above-described examples 1 to 22, the stability of the interface of the connection part of each of the above-described lead-free solder alloys can be maintained, and, as a result, the connection reliability of the solder connection can be increased.

Next, an example 23 shown in FIG. 9 will be described.

The example 23 is a semiconductor module (semiconductor device) 10 as shown in FIG. 9, and is, for example, a power module mounted on a railway vehicle, an automobile, and others. Therefore, a heat-release countermeasure of the power module is required.

When the configuration of the semiconductor module 10 is described, a semiconductor chip 1 is connected to a ceramic substrate (chip supporting member, insulating substrate, connected member) 5 by using a solder alloy (any of the lead-free solder alloys of the examples 1 to 22) 2b of the present embodiment.

Furthermore, the ceramic substrate 5 and a heat-release metal plate (heat-release member) 12 which plays a role of releasing the heat in the operation of the semiconductor chip 1 are connected to each other by using a solder alloy 2c (any of the lead-free solder alloys of the examples 1 to 22), which is the lead-free solder alloy of the present embodiment.

When the detailed structure of the semiconductor module 10 is described, the structure has: the semiconductor chip 1; the ceramic substrate (insulating substrate, connected member) 5 which is a chip supporting member connected to the semiconductor chip 1 via the solder alloy 2b; and a lead (external terminal) 13 which is electrically connected to the semiconductor chip 1.

That is, a conductor part 5d such as a wiring pattern is formed on an upper surface 5a of a substrate main-body part 5e of the ceramic substrate 5, and the semiconductor chip 1 is mounted on the conductor part 5d via the solder alloy (any of the lead-free solder alloys of the examples 1 to 22) 2b.

Moreover, a wiring part (wiring pattern) 5c is formed on the upper surface 5a of the substrate main-body part 5e of the ceramic substrate 5, and the lead 13 is electrically connected to the wiring part 5c. By a wire 11 such as a gold wire or a copper wire, the lead 13 and an electrode pad 1c which is formed on a principal surface 1a of the semiconductor chip 1 are electrically connected to each other and the electrode pad 1c and the wiring part 5c are electrically connected to each other.

A wiring part 5c is formed on a lower surface 5b of the substrate main-body part 5e of the ceramic substrate 5, and the heat-release metal plate (heat-release member) 12 is connected to the wiring part 5c via the solder alloy 2c (any of the lead-free solder alloys of the examples 1 to 22).

Next, an assembly method of the semiconductor module (power module) 10 will be described. The semiconductor module 10 is manufactured by connecting the semiconductor chip 1 and the ceramic substrate 5 to each other by the solder alloy 2b and then connecting the ceramic substrate 5 and the heat-release metal plate 12 to each other by the different solder alloy 2c.

Herein, in the heating for connecting the ceramic substrate 5 and the heat-release metal plate 12 to each other, if the solder alloy 2b, which connects the semiconductor chip 1 and the ceramic substrate 5 to each other, is melted again, the melted solder flows, and a position of the semiconductor chip 1 or others is misaligned, which results in a defect. Generally, in order to prevent the remelting of the solder alloy 2b, it is required for the solder alloy 2c to adopt a material having a melting temperature lower than that of the solder alloy 2b.

However, if any of the solder alloys 2 of the examples 1 to 22 which are the solder alloys 2 (2b, 2c) of the present embodiment is used, the uneven Cu—Sn-based compound layer 4 as shown in FIG. 3 is formed at the connection interface. Therefore, the solder does not flow, and the position of the semiconductor chip 1 is not misaligned.

Therefore, any of the solder alloys 2 of the examples 1 to 22 is applied to the solder alloy 2b of the semiconductor module 10 shown in FIG. 9, and, as similar to the examples 1 to 22, the semiconductor chip 1 and the ceramic substrate 5 of Ni/Cu/Si₃N₄/Cu/Ni in which the Ni plating layer 3 is formed are connected to each other at a connection temperature of 320° C. for retention time of 5 min under a N₂+4% H₂ atmosphere, so that a connection body 9 is obtained.

Furthermore, the solder alloy 2c of any of the examples 1 to 22 is sandwiched by the connection body 9 and the heat-release metal plate 12 which is an AlSiC/Ni substrate, and they are connected at a connection temperature of 320° C. for retention time of 5 min with no load under a N₂+4% H₂ atmosphere, so that the semiconductor module 10 is formed.

Therefore, without remelting the solder alloy 2b of the connection body 9, the ceramic substrate 5 and the heat-release metal plate 12 can be connected to each other.

The semiconductor module 10 can be formed by connecting the lead 13 to the connection body 9 formed as described above and bonding the electrode pad 1c of the principal surface 1a of the semiconductor chip 1 with the wiring part 5c on the ceramic substrate 5 and the lead 13 by the wire 11.

In the semiconductor module 10, note that the Ni plating layer 3 is formed at each of the interface of the connection part between the lead-free solder alloy (solder alloy 2) and the semiconductor chip 1, the interface of the connection part between the above-described lead-free solder alloy and the ceramic substrate 5, and the interface of the connection part between the above-described lead-free solder alloy and the heat-release metal plate 12.

By applying the solder alloy 2 (any of the lead-free solder alloys (solder alloy 2) of the examples 1 to 22) of the present embodiment to each connection part of the semiconductor module 10 as described above, the Cu—Sn compound 6 (see FIG. 8) can be formed to be thick in each interface of each connection part of the lead-free solder alloy. As a result, the interface stability at each connection part can be improved.

As a result, the connection reliability at each connection part of the lead-free solder alloy (solder alloy 2) can be increased.

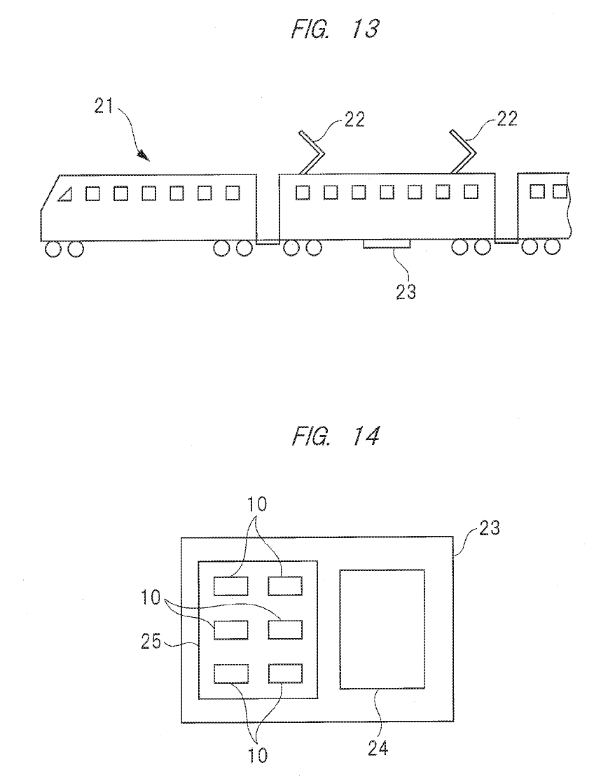

Next, a railway vehicle shown in FIG. 13 on which the semiconductor module 10 is mounted will be described. FIG. 13 is a partial side view showing an example of a railway vehicle on which the semiconductor module 10 using the lead-free solder alloy of the present embodiment is mounted, and FIG. 14 is a plan view showing an example of an internal structure of an inverter set on the vehicle of FIG. 13.

That is, as an example, the semiconductor module 10 of the present embodiment is mounted on an inverter 23 set on a railway vehicle 21 provided with a pantograph 22 which is a power collecting device as shown in FIG. 13.

As shown in FIG. 14, inside the inverter 23, a plurality of semiconductor modules 10 are mounted on a printed board 25, and a cooling device 24 which cools these semiconductor modules 10 is further mounted.

Since the semiconductor module 10 is a power module, the amount of heat generation from the semiconductor chip 1 is large. Therefore, the cooling device 24 is attached so as to be able to cool the plurality of semiconductor modules 10 and cool the inside of the inverter 23.

As described above, the inverter 23 on which the plurality of semiconductor modules 10 using the lead-free solder alloy (solder alloy 2) of the present embodiment are mounted is provided on the railway vehicle 21, so that the reliability of the inverter 23 and the vehicle 21 provided with that can be increased even if the inside of the inverter 23 becomes a high-temperature environment.

Next, an example 24 of the present embodiment shown in FIG. 10 will be described.

A semiconductor device shown in FIG. 10 is, for example, a semiconductor module (power module) 18 for an in-vehicle alternating-current generator.

When the configuration of the semiconductor module 18 is described, the semiconductor module 18 is provided with a semiconductor chip (diode) 1, and a tubular cap (lead electrode body) 15 having a Ni-based plated connection part which is connected to a back surface 1b of the semiconductor chip 1 via a solder alloy (lead-free solder alloy) 2d of the present embodiment.

Furthermore, the semiconductor module 18 is provided with a buffer material 17 for buffering a difference of a thermal expansion coefficient, which has a Ni-based plated connection part connected to a main surface 1a of the semiconductor chip 1 via a solder alloy (lead-free solder alloy) 2e of the present embodiment, and a Cu lead (external terminal) 14 having a Ni-based plated connection part connected to the other surface of the buffer material 17 via a solder alloy (lead-free solder alloy) 2f of the present embodiment.

Moreover, the inside of the tubular cap 15 is filled with a sealing resin 16 which seals the semiconductor chip 1, the buffer material 17, the solder alloys 2d, 2e, and 2f, and a part of the Cu lead 14.

Note that, by arranging (inserting) the buffer material 17 between the semiconductor chip 1 and the Cu lead 14, the stress which is generated in the connection part by a difference in the thermal expansion coefficient of the connected member in cooling after the connection and the temperature cycling can be buffered. The thickness of the buffer material 17 is preferably 30 to 500 μm.

This because, if the thickness of the buffer material 17 is less than 30 μm, cracks occur in the semiconductor chip 1 and intermetallic compounds in some cases since the stress cannot be sufficiently buffered. Also, if the thickness of the buffer material 17 exceeds 500 μm, this thickness may lead to reduction of the connection reliability due to the influence of the difference in the thermal expansion coefficient since each of Al, Mg, Ag, and Zn has a larger thermal expansion coefficient than that of the Cu lead 14.

Meanwhile, as the buffer material 17, any of a “Cu/Invar alloy/Cu composite material”, a “Cu—Mo alloy”, Ti, Mo, and W is preferably used. By providing the buffer material 17, the stress generated in the connection part in the temperature cycling and the cooling after the connection due to the difference in the thermal expansion coefficient between the semiconductor chip 1 and the Cu lead 14 can be buffered.

As a result, the stress applied to the semiconductor chip 1 can be reduced, and formation of cracks in the semiconductor chip 1 can be reduced. Furthermore, in the semiconductor module 18, the connection reliability of the solder connection can be increased.

Herein, FIG. 12 shows evaluations of reliability of the current-conduction thermal fatigue of the semiconductor device 20 shown in FIG. 1 and FIG. 2 which is manufactured for the example 3, the example 9, the example 15, the comparative example 3, and the comparative example 7 shown in FIG. 11.

The test of the above-described current-conduction thermal-fatigue reliability is a test in which a trial is repeated, the trial generating heat by causing a current to flow to the semiconductor chip 1, shutting off the current when the temperature of a lower part of the metal cap reaches 150° C., and cooling it to 50° C.

The thermal resistance of the semiconductor chip 1 is measured after a 5000-cycle test of the current-conduction thermal fatigue test which is a general criterion by which a semiconductor device can obtain certain reliability, and the case that the thermal resistance thereof has an increase rate less than 20% and that the semiconductor chip 1 normally operates is evaluated as “O”, and the other case is evaluated as “X”.

If cracks or voids are generated in the connection part of the solder alloy 2, note that the area for releasing the heat generated in the semiconductor chip 1 to outside is reduced, and the thermal resistance is increased. If the thermal resistance is increased to 20% or more, the chip temperature is rapidly increased, and melting of the solder and interface reactions rapidly progress, and therefore, the connection reliability is reduced.

As shown in FIG. 12, the results of the current-conduction thermal fatigue reliability test under the conditions of the examples 3, 9, and 15 shown in FIG. 11 of the present embodiment are “O”.

As a result, the current-conduction thermal fatigue reliability test can be also cleared by using the solder alloy 2 (any of the lead-free solder alloys of the examples 1 to 22) of the present embodiment.

In the foregoing, the invention made by the present inventors has been concretely described based on the embodiments. However, it is needless to say that the present invention is not limited to the foregoing embodiments and various modifications and alterations can be made within the scope of the present invention.

Note that the present invention is not limited to the above-described embodiments, but includes various modification examples. For example, the above-described embodiments have been explained for easily understanding the present invention, but are not always limited to the ones including all structures explained above.

Also, a part of the structure of one embodiment can be replaced with the structure of the other embodiment, and besides, the structure of the other embodiment can be added to the structure of one embodiment. Further, the other structure can be added to/eliminated from/replaced with a part of the structure of each embodiment. Note that each member and relative size described in the drawings are simplified/idealized in order to understandably describe the present invention, and have more complicated shapes when mounted.

In the above-described embodiments, the cases of the semiconductor device and the semiconductor module provided with the single semiconductor chip 1 have been taken for the explanation. However, the above-described semiconductor device may be, for example, a multi-chip module or others which has a plurality of semiconductor chips, and in which each semiconductor chip 1 is connected to a chip supporting member such as an insulating substrate by the solder alloy (lead-free solder alloy) 2.

### EXPLANATION OF REFERENCE CHARACTERS

1 semiconductor chip

1a principal surface

1b back surface

1c electrode pad

2 solder alloy (lead-free solder alloy)

2a solder foil

2b, 2c, 2d, 2e, and 2f solder alloy (lead-free solder alloy)

3 Ni plating layer

4 Cu—Sn-based compound layer

5 ceramic substrate (chip supporting member, insulating substrate, connected member)

5a upper surface

5b lower surface

5c wiring part

5d conductor part

5e substrate body part

6 Cu—Sn compound

7 void

8 crack progressed part

9 connection body

10 semiconductor module (semiconductor device, power module)

11 wire

12 heat-release metal plate (heat-release member)

13 lead (external terminal.)

14 Cu lead (external terminal)

15 cap (lead)

16 resin

17 buffer material

18 semiconductor module (semiconductor device, power module)

20 semiconductor device

21 vehicle

22 pantagraph

23 inverter

24 cooling device

25 printed board

1. A lead-free solder alloy having a solder composition comprising:
Cu of 5 to 10 weight %;
any one, two, or more of Bi of 1 weight % or more and 4 weight % or less, Sb of 1 weight % or more and less than 10 weight %, and In of 1 weight % or more and 4 weight % or less; and
Sn as a residual.

2. The lead-free solder alloy according to claim 1,
wherein, among the Bi, the Sb, and the In, the Bi is added by 1 weight % or more and 4 weight % or less.

3. The lead-free solder alloy according to claim 1,
wherein, among the Bi, the Sb, and the In, the In is added by 1 weight % or more and 4 weight % or less.

4. The lead-free solder alloy according to claim 1,
wherein, among the Bi, the Sb, and the In, the Sb is added by 1 weight % or more and less than 10 weight %.

5. The lead-free solder alloy according to claim 1,
wherein, among the Bi, the Sb, and the In, the Bi is added by 1 weight % or more and 4 weight % or less, and the In is added by 1 weight % or more and 4 weight % or less.

6. The lead-free solder alloy according to claim 1,
wherein, among the Bi, the Sb, and the In, the Bi is added by 1 weight % or more and 4 weight % or less, and the Sb is added by 1 weight % or more and less than 10 weight %.

7. The lead-free solder alloy according to claim 1,
wherein, among the Bi, the Sb, and the In, the In is added by 1 weight % or more and 4 weight % or less, and the Sb is added by 1 weight % or more and less than 10 weight %.

8. A semiconductor device comprising:
a semiconductor chip;
a chip supporting member connected to the semiconductor chip via a lead-free solder alloy; and
an external terminal electrically connected to the semiconductor chip,
wherein the lead-free solder alloy includes:
Cu of 5 to 10 weight %;
any one, two, or more of Bi of 1 weight % or more and 4 weight % or less, Sb of 1 weight % or more and less than 10 weight %, and In of 1 weight % or more and 4 weight % or less; and
Sn as a residual.

9. The semiconductor device according to claim 8,
wherein, in the lead-free solder alloy, among the Bi, the Sb, and the In, the Bi is added by 1 weight % or more and 4 weight % or less.

10. The semiconductor device according to claim 8,
wherein, in the lead-free solder alloy, among the Bi, the Sb, and the In, the In is added by 1 weight % or more and 4 weight % or less.

11. The semiconductor device according to claim 8,
wherein, in the lead-free solder alloy, among the Bi, the Sb, and the In, the Sb is added by 1 weight % or more and less than 10 weight %.

12. The semiconductor device according to claim 8,
wherein the chip supporting member is an insulating substrate, and
the semiconductor device has a heat-release member connected to the insulating substrate via the lead-free solder alloy.

13. The semiconductor device according to claim 12,
wherein a Ni plating layer is formed on each of an interface of a connection part between the lead-free solder alloy and the semiconductor chip, an interface of a connection part between the lead-free solder alloy and the insulating substrate, and an interface of a connection part between the lead-free solder alloy and the heat-release member.

14. The semiconductor device according to claim 8,
wherein a Cu—Sn compound is formed on each of an interface of a connection part between the chip supporting member and the lead-free solder alloy and an interface of a connection part between the semiconductor chip and the lead-free solder alloy.

15. The semiconductor device according to claim 8,
wherein the semiconductor device is mounted on an inverter provided on a railway vehicle.
